(19) United States
(12) Patent Application Publication
(10) Pub. No.: US 2024/0332275 A1
(43) Pub. Date: Oct. 3, 2024

(54) 3D INTEGRATED IN-PACKAGE MAIN MEMORY

(71) Applicant: Meta Platforms Technologies, LLC, Menlo Park, CA (US)

(72) Inventors: Jaesik Lee, San Jose, CA (US); Rajendra D Pendse, Fremont, CA (US)

(21) Appl. No.: 18/617,009

(22) Filed: Mar. 26, 2024

Related U.S. Application Data
(60) Provisional application No. 63/493,938, filed on Apr. 3, 2023.

(51) Int. Cl. H01L 25/18; H01L 23/00; H01L 23/538; H01L 25/00; H10B 80/00

(52) U.S. Cl. CPC H01L 25/18; H01L 25/50; H10B 80/00; H01L 23/5389; H01L 24/08; H01L 24/16; H01L 24/17; H01L 2224/08145; H01L 2224/16146; H01L 2224/16225; H01L 2224/1703; H01L 2224/17181; H01L 2924/1431; H01L 2924/1436; H01L 2924/1437

(57) ABSTRACT

A multi-chiplet assembly may include a logic chiplet with an active frontside having first active circuitry. A multi-chiplet assembly may include a memory chiplet, electrically coupled to the logic chiplet, with an active frontside having second active circuitry. The active frontside of the logic chiplet may face a first direction, and the active frontside of the memory chiplet may face a second direction opposite the first direction. Various other apparatuses, systems, and methods are also disclosed.

### CROSS REFERENCE TO RELATED APPLICATION

This application claims the benefit of U.S. Provisional Application No. 63/493,938, filed 3 Apr. 2023, and titled 3D IN PACKAGE MEMORY INTEGRATION, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 illustrates an example multi-chiplet package according to at least one embodiment of this disclosure.

FIG. 2 illustrates an example multi-chiplet package according to at least one embodiment of this disclosure.

FIG. 3 illustrates portions of an example multi-chiplet package using face-to-face (F2F) main-memory integration according to at least one embodiment of this disclosure.

FIG. 4 illustrates portions of an example multi-chiplet package using through-package vias for main-memory integration according to at least one embodiment of this disclosure.

FIG. 5 illustrates portions of another example multi-chiplet package according to at least one embodiment of this disclosure.

FIG. 6 illustrates portions of another example multi-chiplet package according to at least one embodiment of this disclosure.

FIG. 7 is a flowchart of an example method for manufacturing a multi-chiplet assembly, such as those illustrated in FIGS. 1, 3, and 5.

FIG. 8 is an illustration of exemplary augmented-reality glasses that may be used in connection with embodiments of this disclosure.

FIG. 9 is an illustration of an exemplary virtual-reality headset that may be used in connection with embodiments of this disclosure.

FIG. 10 is an illustration of exemplary haptic devices that may be used in connection with embodiments of this disclosure.

FIG. 11 is an illustration of an exemplary virtual-reality environment according to embodiments of this disclosure.

FIG. 12 is an illustration of an exemplary augmented-reality environment according to embodiments of this disclosure.

FIG. 13 an illustration of an exemplary system that incorporates an eye-tracking subsystem capable of tracking a user's eye(s).

FIG. 14 is a more detailed illustration of various aspects of the eye-tracking subsystem illustrated in FIG. 13.

FIGS. 15A and 15B are illustrations of an exemplary human-machine interface configured to be worn around a user's lower arm or wrist.

FIGS. 16A and 16B are illustrations of an exemplary schematic diagram with internal components of a wearable system.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

A common structural design of conventional Integrated Circuit (IC) packages involves stacking mass-produced, widely available package-on-package (POP) memories on top of System-on-Chip (SoC) sub-packages. This common structural design often imposes limitations on the memory bandwidth and efficiency of the SoC. In POP configurations, the physical separation and the connection interfaces between the SoC and the memory may introduce latency and bandwidth constraints. Furthermore, this stacked architecture may also limit the form factor of devices. For example, stacked POP memories may increase the height of an IC package, which can be a significant constraint in the design of sleek and compact devices, especially in portable and wearable technology where slim profiles are highly desirable.

The present disclosure is generally directed to various configurations for 3D in-package main-memory integration. Some embodiments of the present disclosure provide structures with 3D stacking of one or more SoC chiplets on top of a main-memory chiplet having through-silicon vias (TSVs), which electrically couple the one or more SoC chiplets to underlying redistribution layers and/or other auxiliary chiplets, such as NAND-memory chiplets or integrated-passive-device (IPD) chiplets. Other embodiments of the present disclosure provide structures with 3D stacking of a memory chiplet on top of one or more SoC chiplets having through-silicon vias (TSVs), which electrically couple the one or more SoC chiplets to underlying redistribution layers and/or a fan-out embedding structure for auxiliary chiplets, such as NAND-memory chiplets or integrated-passive-device (IPD) chiplets.

The disclosed embodiments may improve memory latency and bandwidth by enabling more direct connections between active regions of logic and in-package main-memory chiplets. These embodiments may also enable reduced assembly package sizes while reducing costs and manufacturing complexity, enabling ready integration of chiplets and/or other circuit sub-units that are optimized for specific device and system requirements. These embodiments may also enable use of customized memory chiplets as SoC main memory in addition to or instead of mass-produced, widely available POP memories, which may not satisfy the more unique needs and constraints of more advanced and cutting-edge devices.

Features from any of the embodiments described herein may be used in combination with one another in accordance with the general principles described herein. These and other embodiments, features, and advantages will be more fully understood upon reading the following detailed description in conjunction with the accompanying drawings and claims.

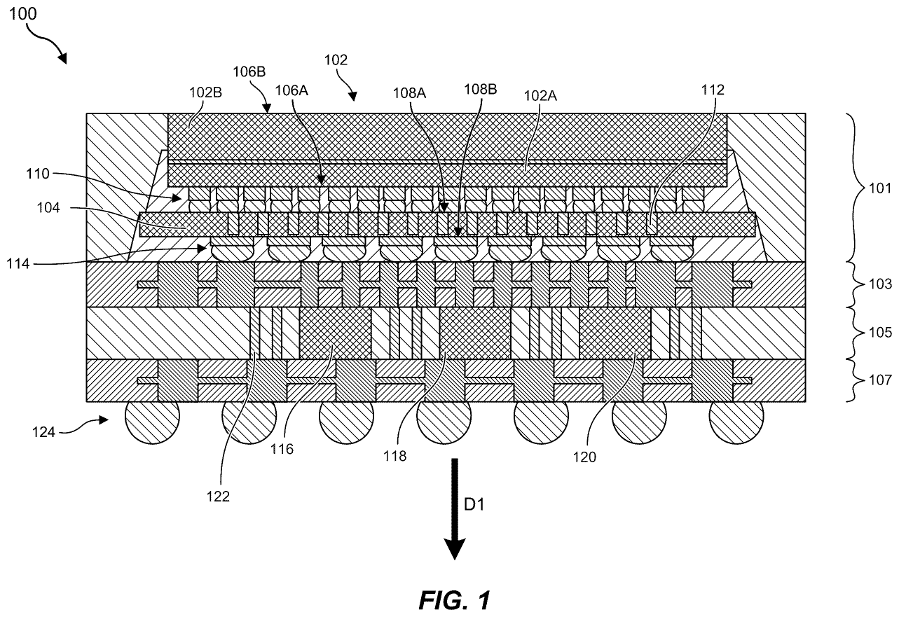

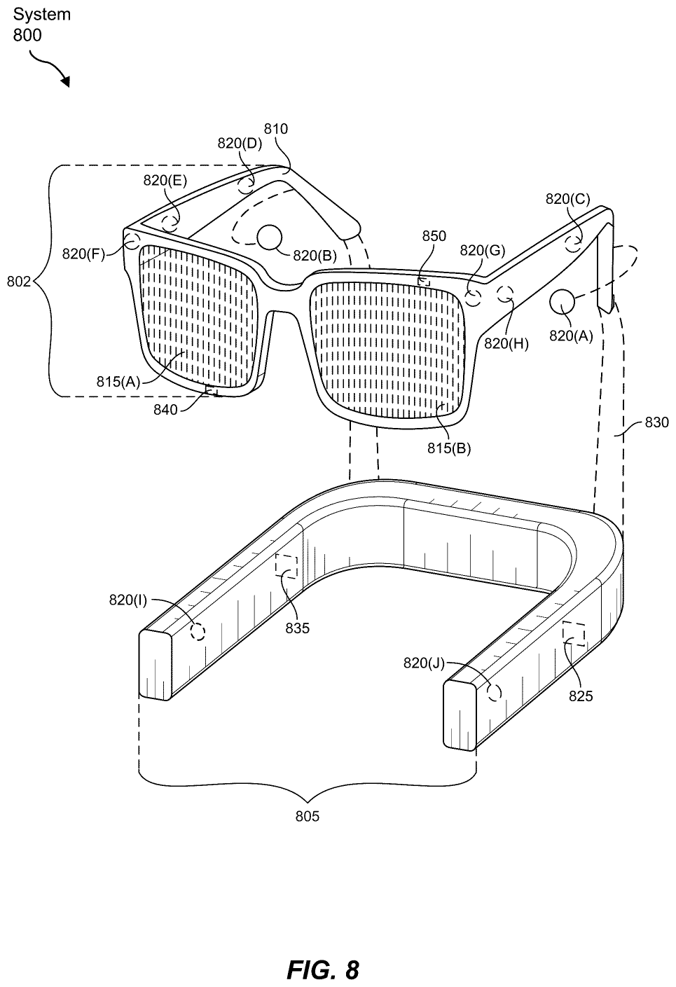

The following will provide, with reference to FIGS. 1-7, detailed descriptions of 3D integrated in-package main memory and/or high-density SoC partitioning. With reference to FIGS. 8-16, the following will provide detailed descriptions of various extended-reality systems and components that may implement embodiments of the present disclosure.

As used herein, the term “chiplet” may generally refer to a die or a thin piece of silicon. For example, and without limitation, a chiplet may include a thin piece of silicon on which components, such as transistors, diodes, resistors, and other components, are housed to fabricate a functional electronic circuit. In some examples, a chiplet may generally refer to a small-scale integrated circuit (IC) having a defined subset of functionality. Multiple chiplets may be combined in a single package assembly or module, with the combination of chiplets being selected and arranged to perform desired functionalities for a particular device and/or system. In some examples, a “logic chiplet” may correspond to a chiplet that contains a majority of the logic components (e.g., transistors) of the electronic circuit of a semiconductor device. In some examples, a logic chiplet may include all or some of the functionality of a SoC. In at least one example, two or more logic chiplets may form a partitioned SoC where each logic chiplet is dedicated to specific functions or tasks of the partitioned SoC. A “memory chiplet” may correspond to a chiplet that contains a majority of the memory components (e.g., static random access memory (SRAM), dynamic random access memory (DRAM), etc.) of the electronic circuit of a semiconductor device. In some examples, a “memory chiplet” may represent or be configured as main memory or cache memory for a connected logic chiplet.

The term “auxiliary chiplet,” as used herein, may refer to a specialized type of chiplet in semiconductor devices. Examples of auxiliary chiplets may include a memory chiplet (e.g., a NAND-flash chiplet), an integrated-passive-device (IPD) chiplet, which may include, for example, resistors, capacitors, inductors, impedance match elements, baluns, microstrip lines, and/or any other suitable electronic components either alone or in combination with a particular IPD package, an integrated-voltage-regulator (IVR) chiplet, which may contain components for voltage regulation to provide a stable power supply, a deep-trench-capacitor (DTC) chiplet, featuring high-density capacitors for efficient energy storage and power management, an input/output (IO) chiplet, which may manage communication with external devices, a direct-to-direct (D2D) interface chiplet, which may enable direct communication and data transfer between chiplets, an analog-to-digital converter (ADC) and/or a digital-to-analog converter (DAC) chiplet, which may convert analog signals to digital data and/or vice versa, a radio-frequency (RF) chiplet, an artificial-intelligence (AI) chiplet, which may accelerate machine-learning and AI computations, an image-signal-processor (ISP) chiplet, which may process and enhance image data from sensors, and/or various co-processor or accelerator chiplets that may enhance specific computational tasks, variations or combinations of one or more of the same, and/or any other suitable auxiliary chiplet that may improve overall system performance and efficiency.

The terms “circuit” and/or “circuitry” as used herein, may generally refer to a complete circular path through which electricity flows. For example, and without limitation, a simple circuit may include a current source, conductors, and a load. The term circuit can be used in a general sense to refer to any fixed path through which electricity, data, or a signal can travel. The term “active circuitry” may represent or include sections of an electronic circuit that contain active electronic components like transistors, diodes, or integrated circuits. Active circuitry may be capable of amplifying power, controlling current flow, or performing other dynamic functions within the circuit. In some examples, “passive circuitry” may include parts of an electronic circuit that consist of passive components such as resistors, capacitors, and inductors, which may be used to attenuate signals, store energy, or provide resistance.

The term “memory,” as used herein, may generally refer to an electronic holding place for instructions and/or data used by a computer processor to perform computing functions. For example, and without limitation, a memory may correspond to metal-oxide-semiconductor (MOS) memory, volatile memory, non-volatile memory, and/or semi-volatile memory. Example types of memory may include static random access memory (SRAM) and/or dynamic access random memory (DRAM). The term “main memory,” as used herein, may generally refer to any memory component within a computing device that stores data and instructions for rapid access by a processor or logical die. In some examples, a main memory may be volatile and/or may require power to maintain the stored information. Main memory may be utilized for temporary storage of data and executable instructions that are actively being accessed or processed by a system's central processing unit (CPU). Main memory may facilitate efficient data retrieval and execution processes, thereby enhancing the overall performance of a computing device. In some examples, main memory may represent or include SRAM that stores frequently accessed data and program instructions for a processor core of a logic chiplet. In some examples, main memory may represent or include DRAM, which may provide a large pool of volatile memory to a processor core of a logic chiplet. In some examples, main memory may represent or include an interface, a controller, and/or a hierarchy of memories, including caches, SRAM, and DRAM, optimized for different access speeds and capacities.

A “backside,” as used herein, may generally refer to a surface portion of a semiconductor chip, such as a chiplet, that is defined by a substrate. A plurality of electronic components and/or electrically conductive layers may be formed on a surface portion of the substrate opposite the backside. In some examples, “backside” may represent or include the surface of the semiconductor chip opposite to the frontside, devoid or substantially devoid of active electronic components. According to some examples, “backside” may represent or include the part of a flip chip that faces upwards, allowing for improved heat dissipation in the configuration.

A “frontside,” as used herein, may generally refer to a portion of a semiconductor chip, such as a chiplet, that is disposed opposite the backside. The frontside may face in a direction opposite a backside of the semiconductor chip and may be defined by and/or formed adjacent electronic components and/or electrically conductive layers disposed on a substrate of the semiconductor chip. In some examples, “frontside” may represent or include the surface of the semiconductor chip where integrated circuits and other functional elements are located. For example, active circuitry, such as active electrical connection regions (e.g., electrically conductive pads such as input/output (I/O) pads), may be exposed at the frontside of the semiconductor chip. Such active electrical connection regions may be positioned and configured to be electrically coupled to one or more components external to the semiconductor chip via suitable electrical interconnects (e.g., solder and/or other electrically conductive bumps, micro-bumps, etc.). According to some examples, “frontside” may represent or include the part of a flip chip that is flipped to face downwards towards the substrate for direct electrical connections.

FIG. 1 illustrates an example multi-chiplet assembly 100 using face-to-face (F2F) in-package main-memory integration. In some examples, multi-chiplet package 100 may include a sub-package layer 101 and/or a sub-package layer 105. As shown, sub-package layer 101 may include a logic chiplet 102 (which may include a first logic die 102A hybrid bonded to a second logic die 102B) and a main-memory chiplet 104. In some examples, logic chiplet 102 may represent a SoC chiplet or portions of a partitioned SoC, and/or main-memory chiplet 104 may represent a memory chiplet that is configured as main memory for logic chiplet 102.

As shown in FIG. 1, logic chiplet 102 and main-memory chiplet 104 may each have a frontside (face side, front surface, or active frontside surface) and a backside (back surface, backside surface, or substrate surface). For example, logic chiplet 102 may have a frontside 106A and a backside 106B disposed opposite frontside 106A, with frontside 106A and backside 106B facing in opposite directions. Similarly, main-memory chiplet 104 may have a frontside 108A and a backside 108B disposed on opposite sides and facing in opposite directions. In the example shown in FIG. 1, logic chiplet 102 is positioned with frontside 106A oriented facing in direction D1, and main-memory chiplet 104 is positioned with frontside 108A oriented facing frontside 106A of logic chiplet 102 and opposite direction D1. In this configuration, active circuitry of frontside 106A of logic chiplet 102 may be coupled to active circuitry of frontside 108A of main-memory chiplet 104 via one or more interconnects 110 (e.g., microbumps). In this example, by placing main-memory chiplet 104 adjacent to frontside 106A of logic chiplet 102 rather than backside 106B, backside 106B of logic chiplet 102 may be left exposed (e.g., to a cooling component or device (not shown)).

In some examples, multi-chiplet package 100 may include additional sub-package layers (e.g., sub-package layer 105) having one or more additional chiplets (e.g., auxiliary chiplets 116, 118, and 120). In at least one example, multi-chiplet package 100 may include one or more distribution layers, interposers, and/or redistribution layers (RDLs) (e.g., a distribution layer 103 and a distribution layer 107) to facilitate routing and interconnection between the components and sub-packages in multi-chiplet package 100. Active circuitry of frontside 106A of logic chiplet 102 may be coupled to distribution layer 103 through vias, such as through-silicon vias 112 of main-memory chiplet 104 or through-package vias of sub-package layer 101 (not shown). RDLs on two sides of a sub-package layer may be connected by through-package vias (such as through-package vias 122). RDLs of two separate sub-package layers may be connected by suitable interconnects, such as solder balls, solder bumps, and/or microbumps. In some examples, active circuitry of frontside 106A of logic chiplet 102 may be coupled to active circuitry of auxiliary chiplets 116, 118, and/or 120 via interconnects 114 and distribution layer 103. In the examples describe herein, sub-package layers and/or chiplets may be coupled to one another via RDL layers and/or any suitable chiplet-to-chiplet bonding technique.

As shown in FIG. 1, an array of interconnects 124 may be disposed on a bottom surface of multi-chiplet package 100. Interconnects 124 may enable mounting and electrical connection between components of multi-chiplet package 100, such as logic chiplet 102, and an external circuit board and/or one or more other electrical components of a device external to multi-chiplet package 100.

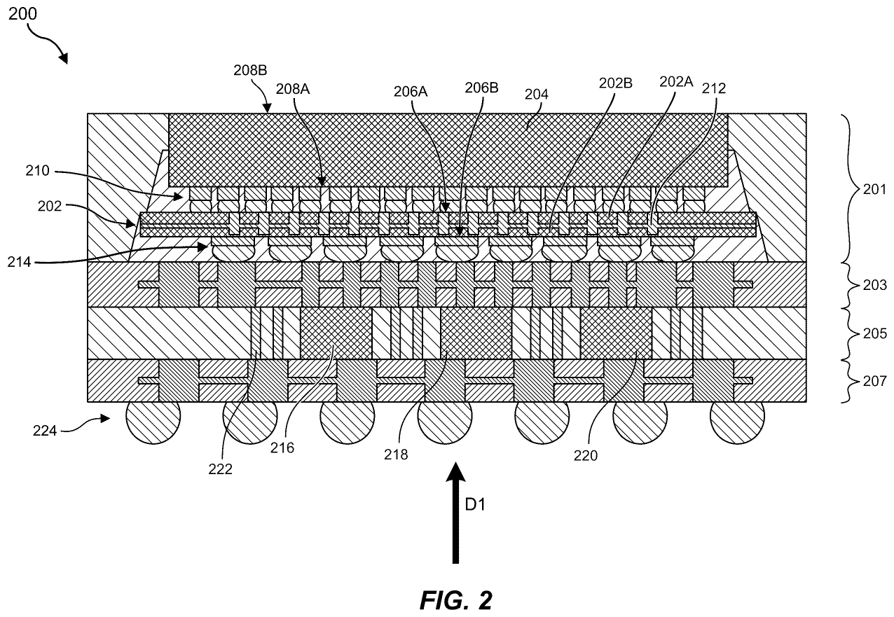

FIG. 2 illustrates another example multi-chiplet assembly 200 using face-to-face (F2F) in-package main-memory integration. In some examples, multi-chiplet package 200 may include a sub-package layer 201 and/or a sub-package layer 205. As shown, sub-package layer 201 may include a logic chiplet 202 (which may include a first logic die 202A hybrid bonded to a second logic die 202B) and a main-memory chiplet 204. In some examples, logic chiplet 202 may represent a SoC chiplet or portions of a partitioned SoC, and/or main-memory chiplet 204 may represent a memory chiplet that is configured as main memory for logic chiplet 202.

As shown in FIG. 2, logic chiplet 202 and main-memory chiplet 204 may each have a frontside (face side, front surface, or active frontside surface) and a backside (back surface, backside surface, or substrate surface). For example, logic chiplet 202 may have a frontside 206A and a backside 206B disposed opposite frontside 206A, with frontside 206A and backside 206B facing in opposite directions. Similarly, main-memory chiplet 204 may have a frontside 208A and a backside 208B disposed on opposite sides and facing in opposite directions. In the example shown in FIG. 2, logic chiplet 202 is positioned with frontside 206A oriented facing in direction D1, and main-memory chiplet 204 is positioned with frontside 208A oriented facing frontside 206A of logic chiplet 202 and opposite direction D1. In this configuration, active circuitry of frontside 206A of logic chiplet 202 may be coupled to active circuitry of frontside 208A of main-memory chiplet 204 via one or more interconnects 210 (e.g., microbumps).

In some examples, multi-chiplet package 200 may include additional sub-package layers (e.g., sub-package layer 205) having one or more additional chiplets (e.g., auxiliary chiplets 216, 218, and 220). In at least one example, multi-chiplet package 200 may include one or more distribution layers, interposers, and/or redistribution layers (RDLs) (e.g., a distribution layer 203 and a distribution layer 207) to facilitate routing and interconnection between the components and sub-packages in multi-chiplet package 200. Active circuitry of frontside 206A of logic chiplet 202 may be coupled to distribution layer 203 through vias, such as through-silicon vias 212 of logic chiplet 102 or through-package vias of sub-package layer 201 (not shown). RDLs on two sides of a sub-package layer may be connected by through-package vias (such as through-package vias 222). RDLs of two separate sub-package layers may be connected by suitable interconnects, such as solder balls, solder bumps, and/or microbumps. In some examples, active circuitry of frontside 206A of logic chiplet 202 may be coupled to active circuitry of auxiliary chiplets 216, 218, and/or 220 via interconnects 214 and distribution layer 203.

As shown in FIG. 2, an array of interconnects 224 may be disposed on a bottom surface of multi-chiplet package 200. Interconnects 224 may enable mounting and electrical connection between components of multi-chiplet package 200, such as logic chiplet 202, and an external circuit board and/or one or more other electrical components of a device external to multi-chiplet package 200.

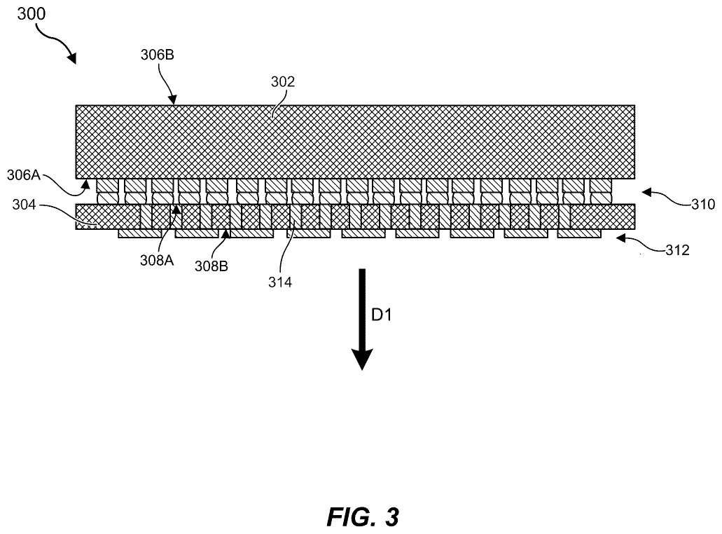

FIG. 3 illustrates a portion 300 of a multi-chiplet package whose bottom side is in the direction D1. As shown, portion 300 may include a first chiplet 302 and a second chiplet 304. In some examples, first chiplet 302 may represent a SoC chiplet or portions of a partitioned SoC, and second chiplet 304 may represent a memory chiplet that is configured as main memory for first chiplet 302. Alternatively, second chiplet 304 may represent a SoC chiplet or portions of a partitioned SoC, and first chiplet 302 may represent a memory chiplet that is configured as main memory for second chiplet 304. As shown in FIG. 3, first and second chiplets 302 and 304 may each have a frontside (face side, front surface, or active frontside surface) and a backside (back surface, backside surface, or substrate surface). For example, first chiplet 302 may have a frontside 306A and a backside 306B disposed opposite frontside 306A, with frontside 306A and backside 306B facing in opposite directions. Similarly, second chiplet 304 may have a frontside 308A and a backside 308B disposed on opposite sides and facing in opposite directions. As shown in FIG. 3, active circuitry of frontside 306A of first chiplet 302 may be coupled to active circuitry of frontside 308A of second chiplet 304 via one or more interconnects 310. Additionally, one or more of active circuitry of frontside 306A of first chiplet 302 and active circuitry of frontside 308A of second chiplet 304 may be coupled to one or more interconnects 312 by through-silicon vias 314 of second chiplet 304.

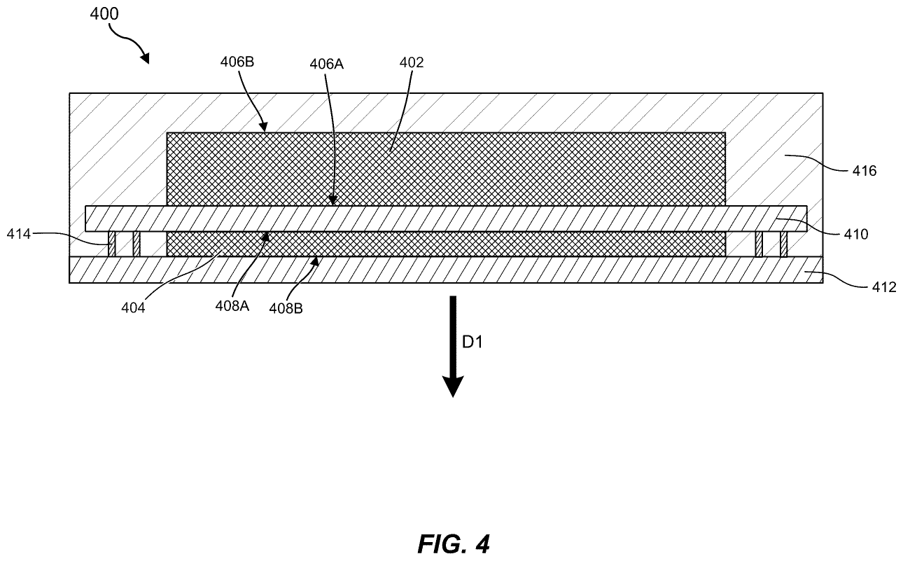

FIG. 4 illustrates a sub-package layer 400 of a multi-chiplet package whose bottom side is in the direction D1. As shown, sub-package layer 400 may include a first chiplet 402 and a second chiplet 404. In some examples, first chiplet 402 may represent a SoC chiplet or portions of a partitioned SoC, and second chiplet 404 may represent a memory chiplet that is configured as main memory for first chiplet 402. Alternatively, second chiplet 404 may represent a SoC chiplet or portions of a partitioned SoC, and first chiplet 402 may represent a memory chiplet that is configured as main memory for second chiplet 404. As shown in FIG. 4, first and second chiplets 402 and 404 may each have a frontside (face side, front surface, or active frontside surface) and a backside (back surface, backside surface, or substrate surface). For example, first chiplet 402 may have a frontside 406A and a backside 406B disposed opposite frontside 406A, with frontside 406A and backside 406B facing in opposite directions. Similarly, second chiplet 404 may have a frontside 408A and a backside 408B disposed on opposite sides and facing in opposite directions. As shown in FIG. 4, active circuitry of frontside 406A of first chiplet 402 may be coupled to active circuitry of frontside 408A of second chiplet 404 through a distribution layer 410. Additionally, one or more of active circuitry of frontside 406A of first chiplet 402 and active circuitry of frontside 408A of second chiplet 404 may be coupled to distribution layer 412 by through-package vias 414 of package substrate 416.

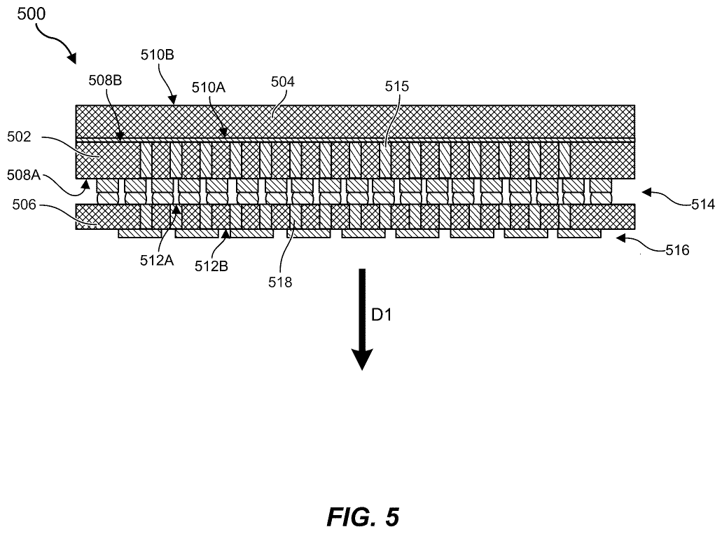

FIG. 5 illustrates a portion 500 of a multi-chiplet package whose bottom side is in the direction D1. As shown, portion 500 may include a first logic chiplet 502, a second logic chiplet 504, and a memory chiplet 506. In some examples, first logic chiplet 502 and second logic chiplet 504 may represent a SoC chiplet or portions of a partitioned SoC, and memory chiplet 506 may represent a memory chiplet that is configured as main memory for one or more of first logic chiplet 502 and/or second logic chiplet 504. As shown in FIG. 5, first logic chiplet 502, second logic chiplet 504, and memory chiplet 506 may each have a frontside (face side, front surface, or active frontside surface) and a backside (back surface, backside surface, or substrate surface). For example, first logic chiplet 502 may have a frontside 508A and a backside 508B disposed opposite frontside 508A, with frontside 508A and backside 508B facing in opposite directions. Similarly, second logic chiplet 504 may have a frontside 510A and a backside 510B disposed on opposite sides and facing in opposite directions, and memory chiplet 506 may have a frontside 512A and a backside 512B disposed on opposite sides and facing in opposite directions. As shown in FIG. 5, active circuitry of frontside 508A of first logic chiplet 502 and/or one or more of interconnects 514 may be coupled to active circuitry of frontside 510A of second logic chiplet 504 via one or more through-silicon vias 515 of first logic chiplet 502. Additionally or alternatively, one or more of active circuitry of frontside 508A of first logic chiplet 502 and active circuitry of frontside 510A of second logic chiplet 504 may be coupled to active circuitry of frontside 512A of memory chiplet 506. Additionally, one or more of active circuitry of frontside 508A of first logic chiplet 502 and active circuitry of frontside 510A of second logic chiplet 504 may be coupled to distribution layer 516 by through-silicon vias 518 of memory chiplet 506.

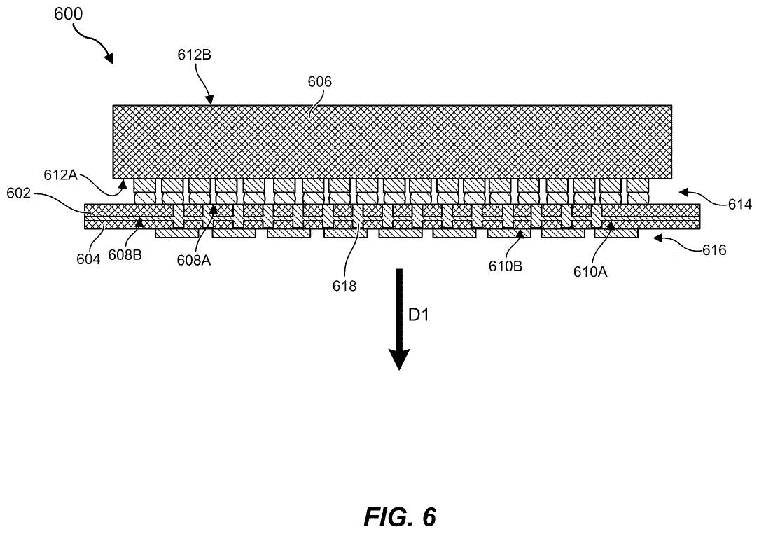

FIG. 6 illustrates a portion 600 of a multi-chiplet package whose bottom side is in the direction D1. As shown, portion 600 may include a first logic chiplet 602, a second logic chiplet 604, and a memory chiplet 606. In some examples, first logic chiplet 602 and second logic chiplet 604 may represent a SoC chiplet or portions of a partitioned SoC, and memory chiplet 606 may represent a memory chiplet that is configured as main memory for one or more of first logic chiplet 602 and/or second logic chiplet 604. As shown in FIG. 6, first logic chiplet 602, second logic chiplet 604, and memory chiplet 606 may each have a frontside (face side, front surface, or active frontside surface) and a backside (back surface, backside surface, or substrate surface). For example, first logic chiplet 602 may have a frontside 608A and a backside 608B disposed opposite frontside 608A, with frontside 608A and backside 608B facing in opposite directions. Similarly, second logic chiplet 604 may have a frontside 610A and a backside 610B disposed on opposite sides and facing in opposite directions, and memory chiplet 606 may have a frontside 612A and a backside 612B disposed on opposite sides and facing in opposite directions.

As shown in FIG. 6, active circuitry of frontside 608A of first logic chiplet 602 and/or active circuitry of frontside 610A of second logic chiplet 604 may be coupled to one or more of interconnects 614 and/or active circuitry of frontside 612A of memory chiplet 606 via one or more through-silicon vias 618 of first logic chiplet 602. Additionally, one or more of active circuitry of frontside 608A of first logic chiplet 602 and active circuitry of frontside 610A of second logic chiplet 604 may be coupled to distribution layer 616 by through-silicon vias 618 of first logic chiplet 602 or second logic chiplet 604.

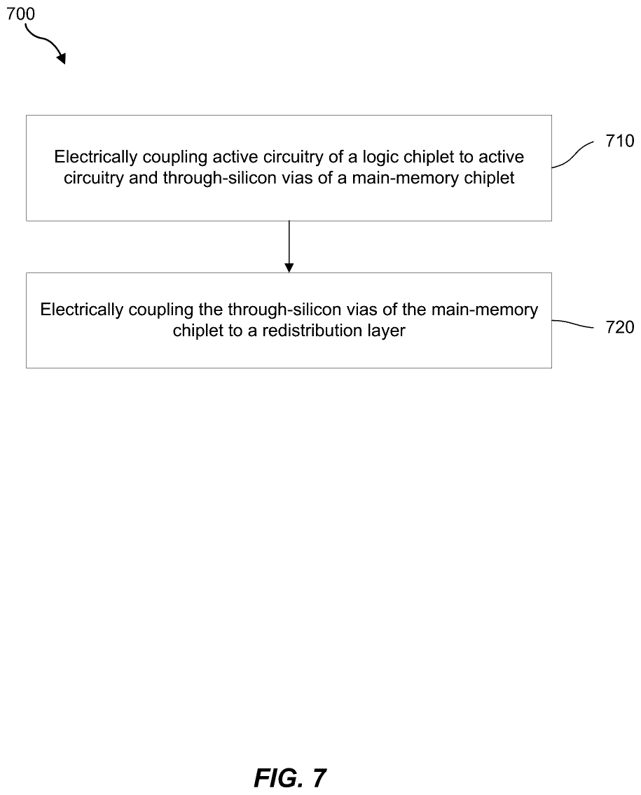

FIG. 7 is a flowchart of an example method for manufacturing a multi-chiplet assembly, such as those illustrated in FIGS. 1, 3, and 5. At step 710, active circuitry of a logic chiplet is electrically coupled to active circuitry and through-silicon vias of a main-memory chiplet. At step 720, the through-silicon vias of the main-memory chiplet are electrically coupled to a redistribution layer.

### EXAMPLE EMBODIMENTS

Example 1: A multi-chiplet assembly including (1) a logic chiplet having an active frontside having first active circuitry and (2) a memory chiplet electrically coupled to the logic chiplet having an active frontside having second active circuitry. In this example, the memory chiplet may be configured as a main memory of the logic chiplet, the active frontside of the logic chiplet may face a first direction, and the active frontside of the memory chiplet may face a second direction opposite the first direction.

Example 2: The multi-chiplet assembly of Example 1 further including a redistribution layer. In this example, the memory chiplet may further include vias through which the first active circuitry of the logic chiplet is electrically coupled to the redistribution layer.

Example 3: The multi-chiplet assembly of any of Examples 1-2 further including an additional logic chiplet directly coupled to the logic chiplet wherein the logic chiplet is positioned between the additional logic chiplet and the memory chiplet.

Example 4: The multi-chiplet assembly of any of Examples 1-3 further including a redistribution layer wherein the logic chiplet further includes vias through which the first active circuitry of the logic chiplet is electrically coupled to the redistribution layer.

Example 5: The multi-chiplet assembly of any of Examples 1-4 further including an additional logic chiplet directly coupled to the logic chiplet wherein the additional logic chiplet includes additional vias through which the first active circuitry of the logic chiplet is electrically coupled to the redistribution layer.

Example 6: The multi-chiplet assembly of any of Examples 1-5 further including (1) through-package vias, (2) a first redistribution layer positioned between the logic chiplet and the memory chiplet, the first redistribution layer coupling the first active circuitry of the logic chiplet to the second active circuitry of the memory chiplet and the through-package vias, and (3) a second redistribution layer electrically coupled to the first active circuitry of the logic chiplet by the through-package vias. In this example, the active frontside of the logic chiplet may face the first direction and the first redistribution layer and the second redistribution layer, the memory chiplet may further include a backside facing the first direction and the second redistribution layer, and the memory chiplet may be positioned between the first redistribution layer and the second redistribution layer.

Example 7: The multi-chiplet assembly of any of Examples 1-6 further including an additional logic chiplet directly coupled to the logic chiplet wherein the logic chiplet is positioned between the additional logic chiplet and the memory chiplet.

Example 8: The multi-chiplet assembly of any of Examples 1-7 further including (1) through-package vias, (2) a first redistribution layer positioned between the logic chiplet and the memory chiplet, the first redistribution layer coupling the first active circuitry of the logic chiplet to the second active circuitry of the memory chiplet and the through-package vias, and (3) a second redistribution layer electrically coupled to the first active circuitry of the logic chiplet by the through-package vias. In this example, the active frontside of the memory chiplet may face the second direction and the first redistribution layer and the second redistribution layer, the logic chiplet may further include a backside facing the second direction and the second redistribution layer, and the logic chiplet may be positioned between the first redistribution layer and the second redistribution layer.

Example 9: The multi-chiplet assembly of any of Examples 1-8 further including an additional logic chiplet directly coupled to the logic chiplet wherein the additional logic chiplet includes additional vias through which the first active circuitry of the logic chiplet is electrically coupled to the first redistribution layer.

Example 10: The multi-chiplet assembly of any of Examples 1-9 further including (1) a first sub-package including the logic chiplet and the memory chiplet and (2) a second sub-package including an auxiliary chiplet.

Example 11: A multi-chiplet assembly including (1) a first sub-package having (A) a top redistribution layer, (B) a bottom redistribution layer, and (C) at least one auxiliary chiplet positioned between the top redistribution layer and the bottom redistribution layer and (2) a second sub-package coupled to the top redistribution layer. The second sub-package may include (D) a logic chiplet having an active frontside having first active circuitry and (E) a memory chiplet electrically coupled to the first logic chiplet having an active frontside having second active circuitry. In this example, the active frontside of the logic chiplet may face a first direction, and the active frontside of the memory chiplet may face a second direction opposite the first direction.

Example 12: The multi-chiplet assembly of Example 11 wherein (1) the memory chiplet is positioned between the logic chiplet and the top redistribution layer and (2) the memory chiplet further includes vias through which the first active circuitry of the logic chiplet is electrically coupled to the top redistribution layer.

Example 13: The multi-chiplet assembly of any of Examples 11-12 further including an additional logic chiplet directly coupled to the logic chiplet wherein the logic chiplet is positioned between the additional logic chiplet and the memory chiplet.

Example 14: The multi-chiplet assembly of any of Examples 11-13 wherein (1) the logic chiplet is positioned between the memory chiplet and the top redistribution layer and (2) the logic chiplet further includes vias through which the first active circuitry of the logic chiplet is electrically coupled to the top redistribution layer.

Example 15: The multi-chiplet assembly of any of Examples 11-14 further including an additional logic chiplet directly coupled to the logic chiplet wherein the additional logic chiplet includes additional vias through which the first active circuitry of the logic chiplet is electrically coupled to the top redistribution layer.

Example 16: The multi-chiplet assembly of any of Examples 11-15 wherein the second sub-package further includes (1) through-package vias and (2) an additional redistribution layer positioned between the logic chiplet and the memory chiplet. In this example, the additional redistribution layer may couple the first active circuitry of the logic chiplet to the second active circuitry of the memory chiplet and the through-package vias, the active frontside of the logic chiplet may face the first direction and the top redistribution layer, the memory chiplet may further include a backside facing the first direction and the top redistribution layer, and the memory chiplet may be positioned between additional redistribution layer and the top redistribution layer.

Example 17: The multi-chiplet assembly of any of Examples 11-16 further including an additional logic chiplet directly coupled to the logic chiplet wherein the logic chiplet is positioned between the additional logic chiplet and the additional redistribution layer.

Example 18: The multi-chiplet assembly of any of Examples 11-17 wherein the second sub-package further includes (1) through-package vias and (2) an additional redistribution layer positioned between the logic chiplet and the memory chiplet. In this example, the additional redistribution layer may couple the first active circuitry of the logic chiplet to the second active circuitry of the memory chiplet and the through-package vias, the active frontside of the memory chiplet may face the second direction and the top redistribution layer, the logic chiplet may further include a backside facing the second direction and the top redistribution layer, and the logic chiplet may be positioned between the additional redistribution layer and the top redistribution layer.

Example 19: The multi-chiplet assembly of any of Examples 11-18 further including an additional logic chiplet directly coupled to the logic chiplet wherein the additional logic chiplet is positioned between the logic chiplet and the top redistribution layer.

Example 20: A method of manufacturing a multi-chiplet assembly including electrically coupling a plurality of vias of a main-memory chiplet to a redistribution layer. In this example, the main-memory chiplet may include the plurality of vias and an active frontside having first active circuitry, and the active frontside of the main-memory chiplet may face away from the redistribution layer. The method may further include electrically coupling a logic chiplet to the main-memory chiplet. In this example, the logic chiplet may include an active frontside having second active circuitry, the active frontside of the main-memory chiplet may face a first direction, the active frontside of the logic chiplet may face a second direction opposite the first direction, and the second active circuitry of the logic chiplet may be electrically coupled to the redistribution layer by the plurality of vias of the main-memory chiplet.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

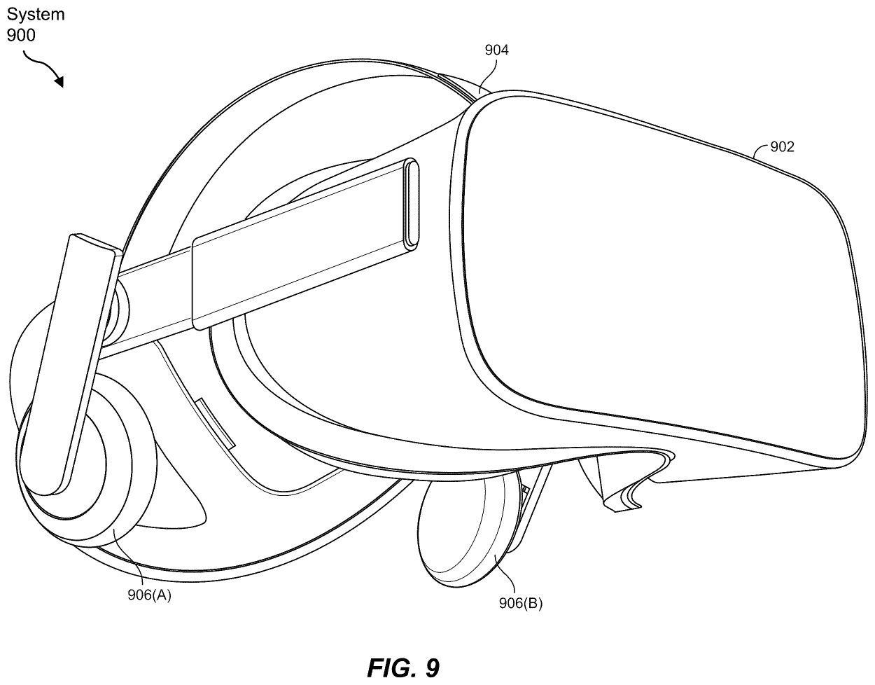

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 800 in FIG. 8) or that visually immerses a user in an artificial reality (such as, e.g., virtual-reality system 900 in FIG. 9). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 8, augmented-reality system 800 may include an eyewear device 802 with a frame 810 configured to hold a left display device 815(A) and a right display device 815(B) in front of a user's eyes. Display devices 815(A) and 815(B) may act together or independently to present an image or series of images to a user. While augmented-reality system 800 includes two displays, embodiments of this disclosure may be implemented in augmented-reality systems with a single NED or more than two NEDs.

In some embodiments, augmented-reality system 800 may include one or more sensors, such as sensor 840. Sensor 840 may generate measurement signals in response to motion of augmented-reality system 800 and may be located on substantially any portion of frame 810. Sensor 840 may represent one or more of a variety of different sensing mechanisms, such as a position sensor, an inertial measurement unit (IMU), a depth camera assembly, a structured light emitter and/or detector, or any combination thereof. In some embodiments, augmented-reality system 800 may or may not include sensor 840 or may include more than one sensor. In embodiments in which sensor 840 includes an IMU, the IMU may generate calibration data based on measurement signals from sensor 840. Examples of sensor 840 may include, without limitation, accelerometers, gyroscopes, magnetometers, other suitable types of sensors that detect motion, sensors used for error correction of the IMU, or some combination thereof.

In some examples, augmented-reality system 800 may also include a microphone array with a plurality of acoustic transducers 820(A)-820(J), referred to collectively as acoustic transducers 820. Acoustic transducers 820 may represent transducers that detect air pressure variations induced by sound waves. Each acoustic transducer 820 may be configured to detect sound and convert the detected sound into an electronic format (e.g., an analog or digital format). The microphone array in FIG. 8 may include, for example, ten acoustic transducers: 820(A) and 820(B), which may be designed to be placed inside a corresponding ear of the user, acoustic transducers 820(C), 820(D), 820(E), 820(F), 820(G), and 820(H), which may be positioned at various locations on frame 810, and/or acoustic transducers 820(I) and 820(J), which may be positioned on a corresponding neckband 805.

In some embodiments, one or more of acoustic transducers 820(A)-(J) may be used as output transducers (e.g., speakers). For example, acoustic transducers 820(A) and/or 820(B) may be earbuds or any other suitable type of headphone or speaker.

The configuration of acoustic transducers 820 of the microphone array may vary. While augmented-reality system 800 is shown in FIG. 8 as having ten acoustic transducers 820, the number of acoustic transducers 820 may be greater or less than ten. In some embodiments, using higher numbers of acoustic transducers 820 may increase the amount of audio information collected and/or the sensitivity and accuracy of the audio information. In contrast, using a lower number of acoustic transducers 820 may decrease the computing power required by an associated controller 850 to process the collected audio information. In addition, the position of each acoustic transducer 820 of the microphone array may vary. For example, the position of an acoustic transducer 820 may include a defined position on the user, a defined coordinate on frame 810, an orientation associated with each acoustic transducer 820, or some combination thereof.

Acoustic transducers 820(A) and 820(B) may be positioned on different parts of the user's ear, such as behind the pinna, behind the tragus, and/or within the auricle or fossa. Or, there may be additional acoustic transducers 820 on or surrounding the ear in addition to acoustic transducers 820 inside the ear canal. Having an acoustic transducer 820 positioned next to an ear canal of a user may enable the microphone array to collect information on how sounds arrive at the ear canal. By positioning at least two of acoustic transducers 820 on either side of a user's head (e.g., as binaural microphones), augmented-reality device 800 may simulate binaural hearing and capture a 3D stereo sound field around about a user's head. In some embodiments, acoustic transducers 820(A) and 820(B) may be connected to augmented-reality system 800 via a wired connection 830, and in other embodiments acoustic transducers 820(A) and 820(B) may be connected to augmented-reality system 800 via a wireless connection (e.g., a BLUETOOTH connection). In still other embodiments, acoustic transducers 820(A) and 820(B) may not be used at all in conjunction with augmented-reality system 800.

Acoustic transducers 820 on frame 810 may be positioned in a variety of different ways, including along the length of the temples, across the bridge, above or below display devices 815(A) and 815(B), or some combination thereof. Acoustic transducers 820 may also be oriented such that the microphone array is able to detect sounds in a wide range of directions surrounding the user wearing the augmented-reality system 800. In some embodiments, an optimization process may be performed during manufacturing of augmented-reality system 800 to determine relative positioning of each acoustic transducer 820 in the microphone array.

In some examples, augmented-reality system 800 may include or be connected to an external device (e.g., a paired device), such as neckband 805. Neckband 805 generally represents any type or form of paired device. Thus, the following discussion of neckband 805 may also apply to various other paired devices, such as charging cases, smart watches, smart phones, wrist bands, other wearable devices, hand-held controllers, tablet computers, laptop computers, other external compute devices, etc.

As shown, neckband 805 may be coupled to eyewear device 802 via one or more connectors. The connectors may be wired or wireless and may include electrical and/or non-electrical (e.g., structural) components. In some cases, eyewear device 802 and neckband 805 may operate independently without any wired or wireless connection between them. While FIG. 8 illustrates the components of eyewear device 802 and neckband 805 in example locations on eyewear device 802 and neckband 805, the components may be located elsewhere and/or distributed differently on eyewear device 802 and/or neckband 805. In some embodiments, the components of eyewear device 802 and neckband 805 may be located on one or more additional peripheral devices paired with eyewear device 802, neckband 805, or some combination thereof.

Pairing external devices, such as neckband 805, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 800 may be provided by a paired device or shared between a paired device and an eyewear device, thus reducing the weight, heat profile, and form factor of the eyewear device overall while still retaining desired functionality. For example, neckband 805 may allow components that would otherwise be included on an eyewear device to be included in neckband 805 since users may tolerate a heavier weight load on their shoulders than they would tolerate on their heads. Neckband 805 may also have a larger surface area over which to diffuse and disperse heat to the ambient environment. Thus, neckband 805 may allow for greater battery and computation capacity than might otherwise have been possible on a stand-alone eyewear device. Since weight carried in neckband 805 may be less invasive to a user than weight carried in eyewear device 802, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 805 may be communicatively coupled with eyewear device 802 and/or to other devices. These other devices may provide certain functions (e.g., tracking, localizing, depth mapping, processing, storage, etc.) to augmented-reality system 800. In the embodiment of FIG. 8, neckband 805 may include two acoustic transducers (e.g., 820 (l) and 820(J)) that are part of the microphone array (or potentially form their own microphone subarray). Neckband 805 may also include a controller 825 and a power source 835.

Acoustic transducers 820(I) and 820(J) of neckband 805 may be configured to detect sound and convert the detected sound into an electronic format (analog or digital). In the embodiment of FIG. 8, acoustic transducers 820(I) and 820(J) may be positioned on neckband 805, thereby increasing the distance between the neckband acoustic transducers 820(I) and 820(J) and other acoustic transducers 820 positioned on eyewear device 802. In some cases, increasing the distance between acoustic transducers 820 of the microphone array may improve the accuracy of beamforming performed via the microphone array. For example, if a sound is detected by acoustic transducers 820(C) and 820(D) and the distance between acoustic transducers 820(C) and 820(D) is greater than, e.g., the distance between acoustic transducers 820(D) and 820(E), the determined source location of the detected sound may be more accurate than if the sound had been detected by acoustic transducers 820(D) and 820(E).

Controller 825 of neckband 805 may process information generated by the sensors on neckband 805 and/or augmented-reality system 800. For example, controller 825 may process information from the microphone array that describes sounds detected by the microphone array. For each detected sound, controller 825 may perform a direction-of-arrival (DOA) estimation to estimate a direction from which the detected sound arrived at the microphone array. As the microphone array detects sounds, controller 825 may populate an audio data set with the information. In embodiments in which augmented-reality system 800 includes an inertial measurement unit, controller 825 may compute all inertial and spatial calculations from the IMU located on eyewear device 802. A connector may convey information between augmented-reality system 800 and neckband 805 and between augmented-reality system 800 and controller 825. The information may be in the form of optical data, electrical data, wireless data, or any other transmittable data form. Moving the processing of information generated by augmented-reality system 800 to neckband 805 may reduce weight and heat in eyewear device 802, making it more comfortable to the user.

Power source 835 in neckband 805 may provide power to eyewear device 802 and/or to neckband 805. Power source 835 may include, without limitation, lithium-ion batteries, lithium-polymer batteries, primary lithium batteries, alkaline batteries, or any other form of power storage. In some cases, power source 835 may be a wired power source. Including power source 835 on neckband 805 instead of on eyewear device 802 may help better distribute the weight and heat generated by power source 835.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 900 in FIG. 9, that mostly or completely covers a user's field of view. Virtual-reality system 900 may include a front rigid body 902 and a band 904 shaped to fit around a user's head. Virtual-reality system 900 may also include output audio transducers 906(A) and 906(B). Furthermore, while not shown in FIG. 9, front rigid body 902 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 800 and/or virtual-reality system 900 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen.

These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 800 and/or virtual-reality system 900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 800 and/or virtual-reality system 900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

Some augmented-reality systems may map a user's and/or device's environment using techniques referred to as “simultaneous location and mapping” (SLAM). SLAM mapping and location identifying techniques may involve a variety of hardware and software tools that can create or update a map of an environment while simultaneously keeping track of a user's location within the mapped environment. SLAM may use many different types of sensors to create a map and determine a user's position within the map.

SLAM techniques may, for example, implement optical sensors to determine a user's location. Radios including WiFi, BLUETOOTH, global positioning system (GPS), cellular or other communication devices may be also used to determine a user's location relative to a radio transceiver or group of transceivers (e.g., a WiFi router or group of GPS satellites). Acoustic sensors such as microphone arrays or 2D or 3D sonar sensors may also be used to determine a user's location within an environment. Augmented-reality and virtual-reality devices (such as systems 800 and 900 of FIGS. 8 and 9, respectively) may incorporate any or all of these types of sensors to perform SLAM operations such as creating and continually updating maps of the user's current environment. In at least some of the embodiments described herein, SLAM data generated by these sensors may be referred to as “environmental data” and may indicate a user's current environment. This data may be stored in a local or remote data store (e.g., a cloud data store) and may be provided to a user's AR/VR device on demand.

When the user is wearing an augmented-reality headset or virtual-reality headset in a given environment, the user may be interacting with other users or other electronic devices that serve as audio sources. In some cases, it may be desirable to determine where the audio sources are located relative to the user and then present the audio sources to the user as if they were coming from the location of the audio source. The process of determining where the audio sources are located relative to the user may be referred to as “localization,” and the process of rendering playback of the audio source signal to appear as if it is coming from a specific direction may be referred to as “spatialization.”

Localizing an audio source may be performed in a variety of different ways. In some cases, an augmented-reality or virtual-reality headset may initiate a DOA analysis to determine the location of a sound source. The DOA analysis may include analyzing the intensity, spectra, and/or arrival time of each sound at the artificial-reality device to determine the direction from which the sounds originated. The DOA analysis may include any suitable algorithm for analyzing the surrounding acoustic environment in which the artificial-reality device is located.

For example, the DOA analysis may be designed to receive input signals from a microphone and apply digital signal processing algorithms to the input signals to estimate the direction of arrival. These algorithms may include, for example, delay and sum algorithms where the input signal is sampled, and the resulting weighted and delayed versions of the sampled signal are averaged together to determine a direction of arrival. A least mean squared (LMS) algorithm may also be implemented to create an adaptive filter. This adaptive filter may then be used to identify differences in signal intensity, for example, or differences in time of arrival. These differences may then be used to estimate the direction of arrival. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct-path audio signal. Those bins having a portion of the direct-path signal may then be analyzed to identify the angle at which a microphone array received the direct-path audio signal. The determined angle may then be used to identify the direction of arrival for the received input signal. Other algorithms not listed above may also be used alone or in combination with the above algorithms to determine DOA.

In some embodiments, different users may perceive the source of a sound as coming from slightly different locations. This may be the result of each user having a unique head-related transfer function (HRTF), which may be dictated by a user's anatomy including ear canal length and the positioning of the ear drum. The artificial-reality device may provide an alignment and orientation guide, which the user may follow to customize the sound signal presented to the user based on their unique HRTF. In some embodiments, an artificial-reality device may implement one or more microphones to listen to sounds within the user's environment. The augmented-reality or virtual-reality headset may use a variety of different array transfer functions (e.g., any of the DOA algorithms identified above) to estimate the direction of arrival for the sounds. Once the direction of arrival has been determined, the artificial-reality device may play back sounds to the user according to the user's unique HRTF. Accordingly, the DOA estimation generated using the array transfer function (ATF) may be used to determine the direction from which the sounds are to be played from. The playback sounds may be further refined based on how that specific user hears sounds according to the HRTF.

In addition to or as an alternative to performing a DOA estimation, an artificial-reality device may perform localization based on information received from other types of sensors. These sensors may include cameras, IR sensors, heat sensors, motion sensors, GPS receivers, or in some cases, sensors that detect a user's eye movements. For example, as noted above, an artificial-reality device may include an eye tracker or gaze detector that determines where the user is looking. Often, the user's eyes will look at the source of the sound, if only briefly. Such clues provided by the user's eyes may further aid in determining the location of a sound source. Other sensors such as cameras, heat sensors, and IR sensors may also indicate the location of a user, the location of an electronic device, or the location of another sound source. Any or all of the above methods may be used individually or in combination to determine the location of a sound source and may further be used to update the location of a sound source over time.

Some embodiments may implement the determined DOA to generate a more customized output audio signal for the user. For instance, an “acoustic transfer function” may characterize or define how a sound is received from a given location. More specifically, an acoustic transfer function may define the relationship between parameters of a sound at its source location and the parameters by which the sound signal is detected (e.g., detected by a microphone array or detected by a user's ear). An artificial-reality device may include one or more acoustic sensors that detect sounds within range of the device. A controller of the artificial-reality device may estimate a DOA for the detected sounds (using, e.g., any of the methods identified above) and, based on the parameters of the detected sounds, may generate an acoustic transfer function that is specific to the location of the device. This customized acoustic transfer function may thus be used to generate a spatialized output audio signal where the sound is perceived as coming from a specific location.

Indeed, once the location of the sound source or sources is known, the artificial-reality device may re-render (i.e., spatialize) the sound signals to sound as if coming from the direction of that sound source. The artificial-reality device may apply filters or other digital signal processing that alter the intensity, spectra, or arrival time of the sound signal. The digital signal processing may be applied in such a way that the sound signal is perceived as originating from the determined location. The artificial-reality device may amplify or subdue certain frequencies or change the time that the signal arrives at each ear. In some cases, the artificial-reality device may create an acoustic transfer function that is specific to the location of the device and the detected direction of arrival of the sound signal. In some embodiments, the artificial-reality device may re-render the source signal in a stereo device or multi-speaker device (e.g., a surround sound device). In such cases, separate and distinct audio signals may be sent to each speaker. Each of these audio signals may be altered according to the user's HRTF and according to measurements of the user's location and the location of the sound source to sound as if they are coming from the determined location of the sound source. Accordingly, in this manner, the artificial-reality device (or speakers associated with the device) may re-render an audio signal to sound as if originating from a specific location.

As noted, artificial-reality systems 800 and 900 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

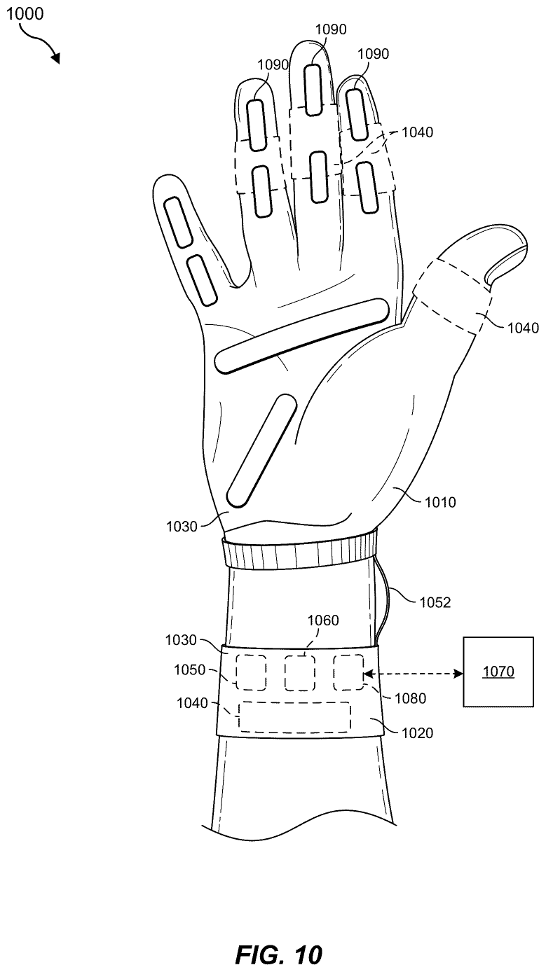

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 10 illustrates a vibrotactile system 1000 in the form of a wearable glove (haptic device 1010) and wristband (haptic device 1020). Haptic device 1010 and haptic device 1020 are shown as examples of wearable devices that include a flexible, wearable textile material 1030 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 1040 may be positioned at least partially within one or more corresponding pockets formed in textile material 1030 of vibrotactile system 1000. Vibrotactile devices 1040 may be positioned in locations to provide a vibrating sensation (e.g., haptic feedback) to a user of vibrotactile system 1000. For example, vibrotactile devices 1040 may be positioned against the user's finger(s), thumb, or wrist, as shown in FIG. 10. Vibrotactile devices 1040 may, in some examples, be sufficiently flexible to conform to or bend with the user's corresponding body part(s).

A power source 1050 (e.g., a battery) for applying a voltage to the vibrotactile devices 1040 for activation thereof may be electrically coupled to vibrotactile devices 1040, such as via conductive wiring 1052. In some examples, each of vibrotactile devices 1040 may be independently electrically coupled to power source 1050 for individual activation. In some embodiments, a processor 1060 may be operatively coupled to power source 1050 and configured (e.g., programmed) to control activation of vibrotactile devices 1040.

Vibrotactile system 1000 may be implemented in a variety of ways. In some examples, vibrotactile system 1000 may be a standalone system with integral subsystems and components for operation independent of other devices and systems. As another example, vibrotactile system 1000 may be configured for interaction with another device or system 1070.

For example, vibrotactile system 1000 may, in some examples, include a communications interface 1080 for receiving and/or sending signals to the other device or system 1070. The other device or system 1070 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 1080 may enable communications between vibrotactile system 1000 and the other device or system 1070 via a wireless (e.g., Wi-Fi, BLUETOOTH, cellular, radio, etc.) link or a wired link. If present, communications interface 1080 may be in communication with processor 1060, such as to provide a signal to processor 1060 to activate or deactivate one or more of the vibrotactile devices 1040.

Vibrotactile system 1000 may optionally include other subsystems and components, such as touch-sensitive pads 1090, pressure sensors, motion sensors, position sensors, lighting elements, and/or user interface elements (e.g., an on/off button, a vibration control element, etc.). During use, vibrotactile devices 1040 may be configured to be activated for a variety of different reasons, such as in response to the user's interaction with user interface elements, a signal from the motion or position sensors, a signal from the touch-sensitive pads 1090, a signal from the pressure sensors, a signal from the other device or system 1070, etc.

Although power source 1050, processor 1060, and communications interface 1080 are illustrated in FIG. 10 as being positioned in haptic device 1020, the present disclosure is not so limited. For example, one or more of power source 1050, processor 1060, or communications interface 1080 may be positioned within haptic device 1010 or within another wearable textile.

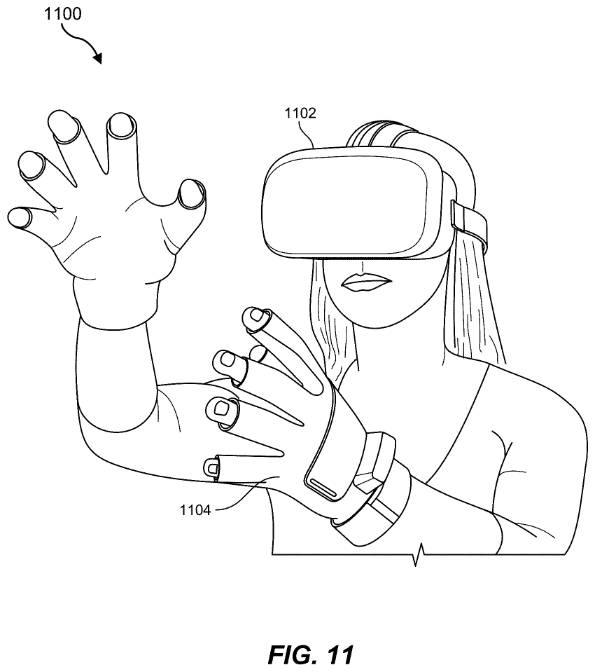

Haptic wearables, such as those shown in and described in connection with FIG. 10, may be implemented in a variety of types of artificial-reality systems and environments. FIG. 11 shows an example artificial-reality environment 1100 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1102 generally represents any type or form of virtual-reality system, such as virtual-reality system 900 in FIG. 9. Haptic device 1104 generally represents any type or form of wearable device, worn by a user of an artificial-reality system, that provides haptic feedback to the user to give the user the perception that he or she is physically engaging with a virtual object. In some embodiments, haptic device 1104 may provide haptic feedback by applying vibration, motion, and/or force to the user. For example, haptic device 1104 may limit or augment a user's movement. To give a specific example, haptic device 1104 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 1104 to send action requests to a console. Examples of action requests include, without limitation, requests to start an application and/or end the application and/or requests to perform a particular action within the application.

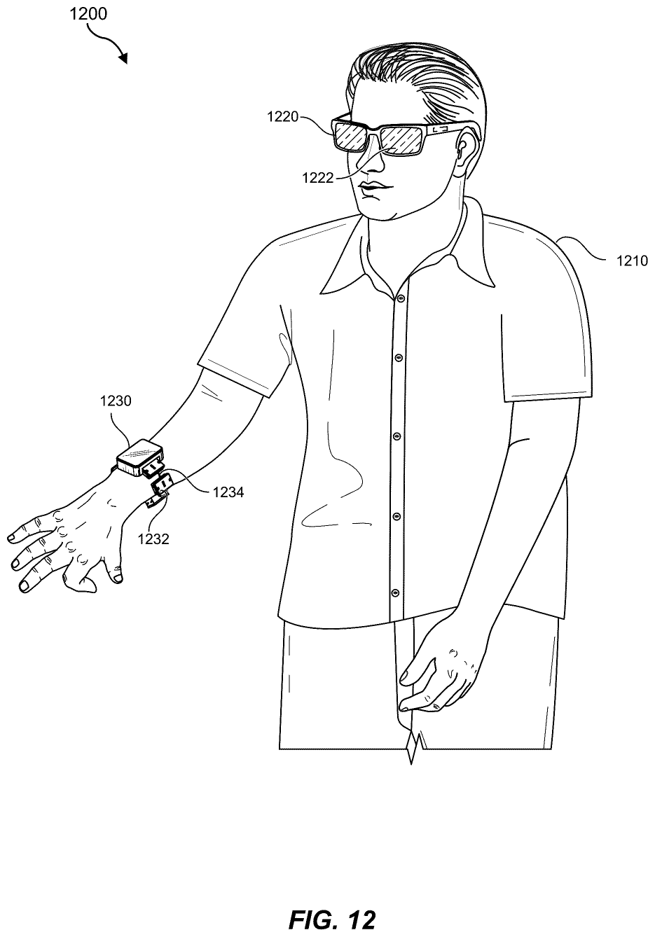

While haptic interfaces may be used with virtual-reality systems, as shown in FIG. 11, haptic interfaces may also be used with augmented-reality systems, as shown in FIG. 12. FIG. 12 is a perspective view of a user 1210 interacting with an augmented-reality system 1200. In this example, user 1210 may wear a pair of augmented-reality glasses 1220 that may have one or more displays 1222 and that are paired with a haptic device 1230. In this example, haptic device 1230 may be a wristband that includes a plurality of band elements 1232 and a tensioning mechanism 1234 that connects band elements 1232 to one another.

One or more of band elements 1232 may include any type or form of actuator suitable for providing haptic feedback. For example, one or more of band elements 1232 may be configured to provide one or more of various types of cutaneous feedback, including vibration, force, traction, texture, and/or temperature. To provide such feedback, band elements 1232 may include one or more of various types of actuators. In one example, each of band elements 1232 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 1010, 1020, 1104, and 1230 may include any suitable number and/or type of haptic transducer, sensor, and/or feedback mechanism. For example, haptic devices 1010, 1020, 1104, and 1230 may include one or more mechanical transducers, piezoelectric transducers, and/or fluidic transducers. Haptic devices 1010, 1020, 1104, and 1230 may also include various combinations of different types and forms of transducers that work together or independently to enhance a user's artificial-reality experience. In one example, each of band elements 1232 of haptic device 1230 may include a vibrotactor (e.g., a vibrotactile actuator) configured to vibrate in unison or independently to provide one or more of various types of haptic sensations to a user.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

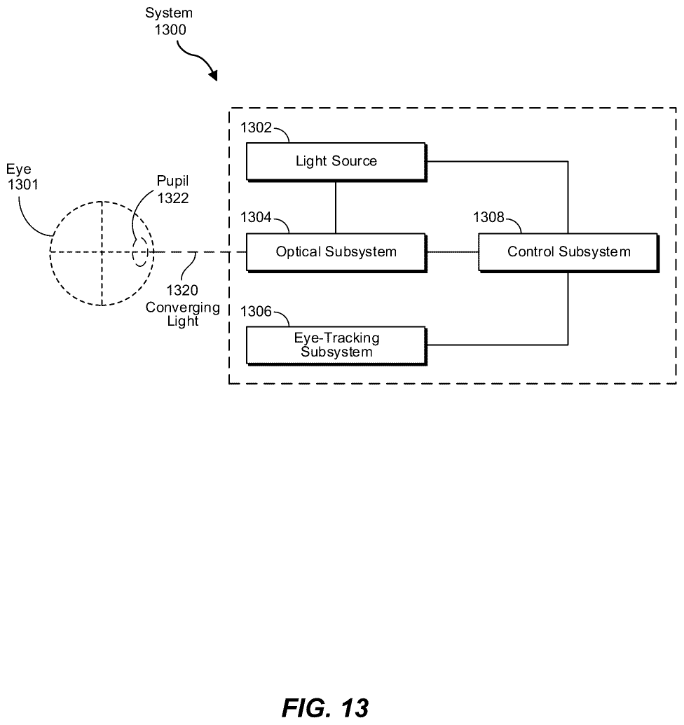

FIG. 13 is an illustration of an exemplary system 1300 that incorporates an eye-tracking subsystem capable of tracking a user's eye(s). As depicted in FIG. 13, system 1300 may include a light source 1302, an optical subsystem 1304, an eye-tracking subsystem 1306, and/or a control subsystem 1308. In some examples, light source 1302 may generate light for an image (e.g., to be presented to an eye 1301 of the viewer). Light source 1302 may represent any of a variety of suitable devices. For example, light source 1302 can include a two-dimensional projector (e.g., a LCOS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 1304 may receive the light generated by light source 1302 and generate, based on the received light, converging light 1320 that includes the image. In some examples, optical subsystem 1304 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 1320. Further, various mechanical couplings may serve to maintain the relative spacing and/or the orientation of the optical components in any suitable combination.

In one embodiment, eye-tracking subsystem 1306 may generate tracking information indicating a gaze angle of an eye 1301 of the viewer. In this embodiment, control subsystem 1308 may control aspects of optical subsystem 1304 (e.g., the angle of incidence of converging light 1320) based at least in part on this tracking information. Additionally, in some examples, control subsystem 1308 may store and utilize historical tracking information (e.g., a history of the tracking information over a given duration, such as the previous second or fraction thereof) to anticipate the gaze angle of eye 1301 (e.g., an angle between the visual axis and the anatomical axis of eye 1301). In some embodiments, eye-tracking subsystem 1306 may detect radiation emanating from some portion of eye 1301 (e.g., the cornea, the iris, the pupil, or the like) to determine the current gaze angle of eye 1301. In other examples, eye-tracking subsystem 1306 may employ a wavefront sensor to track the current location of the pupil.

Any number of techniques can be used to track eye 1301. Some techniques may involve illuminating eye 1301 with infrared light and measuring reflections with at least one optical sensor that is tuned to be sensitive to the infrared light. Information about how the infrared light is reflected from eye 1301 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 1306 may be digitized (i.e., converted to an electronic signal). Further, the sensor may transmit a digital representation of this electronic signal to one or more processors (for example, processors associated with a device including eye-tracking subsystem 1306). Eye-tracking subsystem 1306 may include any of a variety of sensors in a variety of different configurations. For example, eye-tracking subsystem 1306 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 1306 to track the movement of eye 1301. In another example, these processors may track the movements of eye 1301 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 1306 may be programmed to use an output of the sensor(s) to track movement of eye 1301. In some embodiments, eye-tracking subsystem 1306 may analyze the digital representation generated by the sensors to extract eye rotation information from changes in reflections. In one embodiment, eye-tracking subsystem 1306 may use corneal reflections or glints (also known as Purkinje images) and/or the center of the eye's pupil 1322 as features to track over time.

In some embodiments, eye-tracking subsystem 1306 may use the center of the eye's pupil 1322 and infrared or near-infrared, non-collimated light to create corneal reflections. In these embodiments, eye-tracking subsystem 1306 may use the vector between the center of the eye's pupil 1322 and the corneal reflections to compute the gaze direction of eye 1301. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 1306 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 1301 may act as a retroreflector as the light reflects off the retina, thereby creating a bright pupil effect similar to a red-eye effect in photography. If the illumination source is offset from the optical path, then the eye's pupil 1322 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 1308 may control light source 1302 and/or optical subsystem 1304 to reduce optical aberrations (e.g., chromatic aberrations and/or monochromatic aberrations) of the image that may be caused by or influenced by eye 1301. In some examples, as mentioned above, control subsystem 1308 may use the tracking information from eye-tracking subsystem 1306 to perform such control. For example, in controlling light source 1302, control subsystem 1308 may alter the light generated by light source 1302 (e.g., by way of image rendering) to modify (e.g., pre-distort) the image so that the aberration of the image caused by eye 1301 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

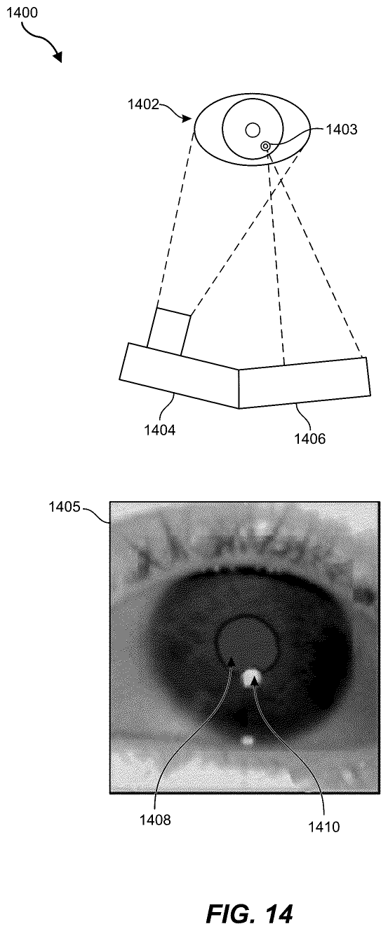

FIG. 14 is a more detailed illustration of various aspects of the eye-tracking subsystem illustrated in FIG. 13. As shown in this figure, an eye-tracking subsystem 1400 may include at least one source 1404 and at least one sensor 1406. Source 1404 generally represents any type or form of element capable of emitting radiation. In one example, source 1404 may generate visible, infrared, and/or near-infrared radiation. In some examples, source 1404 may radiate non-collimated infrared and/or near-infrared portions of the electromagnetic spectrum towards an eye 1402 of a user. Source 1404 may utilize a variety of sampling rates and speeds. For example, the disclosed systems may use sources with higher sampling rates in order to capture fixational eye movements of a user's eye 1402 and/or to correctly measure saccade dynamics of the user's eye 1402. As noted above, any type or form of eye-tracking technique may be used to track the user's eye 1402, including optical-based eye-tracking techniques, ultrasound-based eye-tracking techniques, etc.

Sensor 1406 generally represents any type or form of element capable of detecting radiation, such as radiation reflected off the user's eye 1402. Examples of sensor 1406 include, without limitation, a charge coupled device (CCD), a photodiode array, a complementary metal-oxide-semiconductor (CMOS) based sensor device, and/or the like. In one example, sensor 1406 may represent a sensor having predetermined parameters, including, but not limited to, a dynamic resolution range, linearity, and/or other characteristic selected and/or designed specifically for eye tracking.

As detailed above, eye-tracking subsystem 1400 may generate one or more glints. As detailed above, a glint 1403 may represent reflections of radiation (e.g., infrared radiation from an infrared source, such as source 1404) from the structure of the user's eye. In various embodiments, glint 1403 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 14 shows an example image 1405 captured by an eye-tracking subsystem, such as eye-tracking subsystem 1400. In this example, image 1405 may include both the user's pupil 1408 and a glint 1410 near the same. In some examples, pupil 1408 and/or glint 1410 may be identified using an artificial-intelligence-based algorithm, such as a computer-vision-based algorithm. In one embodiment, image 1405 may represent a single frame in a series of frames that may be analyzed continuously in order to track the eye 1402 of the user. Further, pupil 1408 and/or glint 1410 may be tracked over a period of time to determine a user's gaze.

In one example, eye-tracking subsystem 1400 may be configured to identify and measure the inter-pupillary distance (IPD) of a user. In some embodiments, eye-tracking subsystem 1400 may measure and/or calculate the IPD of the user while the user is wearing the artificial reality system. In these embodiments, eye-tracking subsystem 1400 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 1300 and/or eye-tracking subsystem 1400 may be incorporated into augmented-reality system 800 in FIG. 8 and/or virtual-reality system 900 in FIG. 9 to enable these systems to perform various eye-tracking tasks (including one or more of the eye-tracking operations described herein).

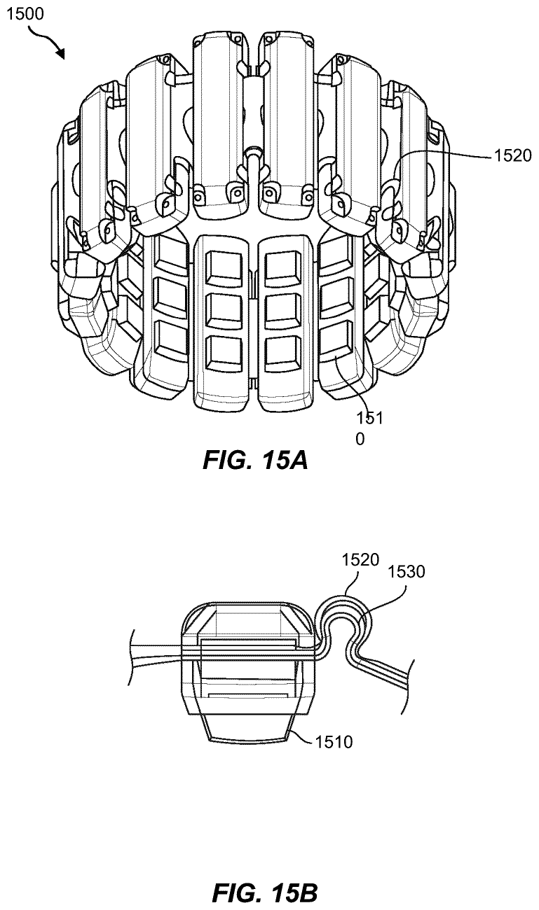

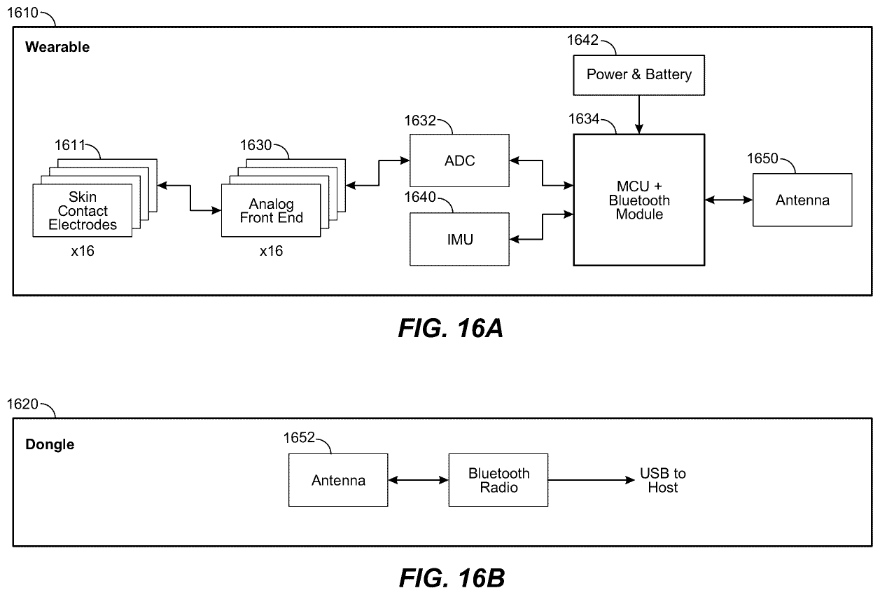

FIG. 15A illustrates an exemplary human-machine interface (also referred to herein as an EMG control interface) configured to be worn around a user's lower arm or wrist as a wearable system 1500. In this example, wearable system 1500 may include sixteen neuromuscular sensors 1510 (e.g., EMG sensors) arranged circumferentially around an elastic band 1520 with an interior surface 1530 configured to contact a user's skin. However, any suitable number of neuromuscular sensors may be used. The number and arrangement of neuromuscular sensors may depend on the particular application for which the wearable device is used. For example, a wearable armband or wristband can be used to generate control information for controlling an augmented reality system, a robot, controlling a vehicle, scrolling through text, controlling a virtual avatar, or any other suitable control task. As shown, the sensors may be coupled together using flexible electronics incorporated into the wireless device. FIG. 15B illustrates a cross-sectional view through one of the sensors of the wearable device shown in FIG. 15A. In some embodiments, the output of one or more of the sensing components can be optionally processed using hardware signal processing circuitry (e.g., to perform amplification, filtering, and/or rectification). In other embodiments, at least some signal processing of the output of the sensing components can be performed in software. Thus, signal processing of signals sampled by the sensors can be performed in hardware, software, or by any suitable combination of hardware and software, as aspects of the technology described herein are not limited in this respect. A non-limiting example of a signal processing chain used to process recorded data from sensors 1510 is discussed in more detail below with reference to FIGS. 16A and 16B.

FIGS. 16A and 16B illustrate an exemplary schematic diagram with internal components of a wearable system with EMG sensors. As shown, the wearable system may include a wearable portion 1610 (FIG. 16A) and a dongle portion 1620 (FIG. 16B) in communication with the wearable portion 1610 (e.g., via BLUETOOTH or another suitable wireless communication technology). As shown in FIG. 16A, the wearable portion 1610 may include skin contact electrodes 1611, examples of which are described in connection with FIGS. 15A and 15B. The output of the skin contact electrodes 1611 may be provided to analog front end 1630, which may be configured to perform analog processing (e.g., amplification, noise reduction, filtering, etc.) on the recorded signals. The processed analog signals may then be provided to analog-to-digital converter 1632, which may convert the analog signals to digital signals that can be processed by one or more computer processors. An example of a computer processor that may be used in accordance with some embodiments is microcontroller (MCU) 1634, illustrated in FIG. 16A. As shown, MCU 1634 may also include inputs from other sensors (e.g., IMU sensor 1640), and power and battery module 1642. The output of the processing performed by MCU 1634 may be provided to antenna 1650 for transmission to dongle portion 1620 shown in FIG. 16B.

Dongle portion 1620 may include antenna 1652, which may be configured to communicate with antenna 1650 included as part of wearable portion 1610. Communication between antennas 1650 and 1652 may occur using any suitable wireless technology and protocol, non-limiting examples of which include radiofrequency signaling and BLUETOOTH. As shown, the signals received by antenna 1652 of dongle portion 1620 may be provided to a host computer for further processing, display, and/or for effecting control of a particular physical or virtual object or objects.

Although the examples provided with reference to FIGS. 15A-15B and FIGS. 16A-16B are discussed in the context of interfaces with EMG sensors, the techniques described herein for reducing electromagnetic interference can also be implemented in wearable interfaces with other types of sensors including, but not limited to, mechanomyography (MMG) sensors, sonomyography (SMG) sensors, and electrical impedance tomography (EIT) sensors. The techniques described herein for reducing electromagnetic interference can also be implemented in wearable interfaces that communicate with computer hosts through wires and cables (e.g., USB cables, optical fiber cables, etc.).

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. For example, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A multi-chiplet assembly comprising:
a logic chiplet comprising an active frontside having first active circuitry; and
a memory chiplet electrically coupled to the logic chiplet and comprising an active frontside having second active circuitry, wherein:
the memory chiplet is configured as a main memory of the logic chiplet;
the active frontside of the logic chiplet faces a first direction; and
the active frontside of the memory chiplet faces a second direction opposite the first direction.

2. The multi-chiplet assembly of claim 1 further comprising a redistribution layer, wherein the memory chiplet further comprises vias through which the first active circuitry of the logic chiplet is electrically coupled to the redistribution layer.

3. The multi-chiplet assembly of claim 2 further comprising an additional logic chiplet directly coupled to the logic chiplet, wherein the logic chiplet is positioned between the additional logic chiplet and the memory chiplet.

4. The multi-chiplet assembly of claim 1 further comprising a redistribution layer, wherein the logic chiplet further comprises vias through which the first active circuitry of the logic chiplet is electrically coupled to the redistribution layer.

5. The multi-chiplet assembly of claim 4 further comprising an additional logic chiplet directly coupled to the logic chiplet, wherein the additional logic chiplet comprises additional vias through which the first active circuitry of the logic chiplet is electrically coupled to the redistribution layer.

6. The multi-chiplet assembly of claim 1 further comprising:
through-package vias;
a first redistribution layer positioned between the logic chiplet and the memory chiplet, the first redistribution layer coupling the first active circuitry of the logic chiplet to the second active circuitry of the memory chiplet and the through-package vias; and
a second redistribution layer electrically coupled to the first active circuitry of the logic chiplet by the through-package vias, wherein:
the active frontside of the logic chiplet faces the first direction and the first redistribution layer and the second redistribution layer;
the memory chiplet further comprises a backside facing the first direction and the second redistribution layer; and
the memory chiplet is positioned between the first redistribution layer and the second redistribution layer.

7. The multi-chiplet assembly of claim 6 further comprising an additional logic chiplet directly coupled to the logic chiplet, wherein the logic chiplet is positioned between the additional logic chiplet and the memory chiplet.

8. The multi-chiplet assembly of claim 1 further comprising:
through-package vias;
a first redistribution layer positioned between the logic chiplet and the memory chiplet, the first redistribution layer coupling the first active circuitry of the logic chiplet to the second active circuitry of the memory chiplet and the through-package vias; and
a second redistribution layer electrically coupled to the first active circuitry of the logic chiplet by the through-package vias, wherein:
the active frontside of the memory chiplet faces the second direction and the first redistribution layer and the second redistribution layer;
the logic chiplet further comprises a backside facing the second direction and the second redistribution layer; and
the logic chiplet is positioned between the first redistribution layer and the second redistribution layer.

9. The multi-chiplet assembly of claim 8 further comprising an additional logic chiplet directly coupled to the logic chiplet, wherein the additional logic chiplet comprises additional vias through which the first active circuitry of the logic chiplet is electrically coupled to the first redistribution layer.

10. The multi-chiplet assembly of claim 1 further comprising:
a first sub-package comprising the logic chiplet and the memory chiplet; and
a second sub-package comprising an auxiliary chiplet.

11. A multi-chiplet assembly comprising:
a first sub-package comprising:
a top redistribution layer;
a bottom redistribution layer; and
at least one auxiliary chiplet positioned between the top redistribution layer and the bottom redistribution layer; and
a second sub-package coupled to the top redistribution layer and comprising:
a logic chiplet comprising an active frontside having first active circuitry;
a memory chiplet electrically coupled to the first logic chiplet and comprising an active frontside having second active circuitry, wherein:
the active frontside of the logic chiplet faces a first direction; and
the active frontside of the memory chiplet faces a second direction opposite the first direction.

12. The multi-chiplet assembly of claim 11, wherein:
the memory chiplet is positioned between the logic chiplet and the top redistribution layer; and
the memory chiplet further comprises vias through which the first active circuitry of the logic chiplet is electrically coupled to the top redistribution layer.

13. The multi-chiplet assembly of claim 12 further comprising an additional logic chiplet directly coupled to the logic chiplet, wherein the logic chiplet is positioned between the additional logic chiplet and the memory chiplet.

14. The multi-chiplet assembly of claim 11, wherein:
the logic chiplet is positioned between the memory chiplet and the top redistribution layer; and
the logic chiplet further comprises vias through which the first active circuitry of the logic chiplet is electrically coupled to the top redistribution layer.

15. The multi-chiplet assembly of claim 14 further comprising an additional logic chiplet directly coupled to the logic chiplet, wherein the additional logic chiplet comprises additional vias through which the first active circuitry of the logic chiplet is electrically coupled to the top redistribution layer.

16. The multi-chiplet assembly of claim 11, wherein:
the second sub-package further comprises:
through-package vias; and
an additional redistribution layer positioned between the logic chiplet and the memory chiplet, the additional redistribution layer coupling the first active circuitry of the logic chiplet to the second active circuitry of the memory chiplet and the through-package vias; and
the active frontside of the logic chiplet faces the first direction and the top redistribution layer;
the memory chiplet further comprises a backside facing the first direction and the top redistribution layer; and
the memory chiplet is positioned between additional redistribution layer and the top redistribution layer.

17. The multi-chiplet assembly of claim 16 further comprising an additional logic chiplet directly coupled to the logic chiplet, wherein the logic chiplet is positioned between the additional logic chiplet and the additional redistribution layer.

18. The multi-chiplet assembly of claim 11, wherein:
the second sub-package further comprises:
through-package vias; and
an additional redistribution layer positioned between the logic chiplet and the memory chiplet, the additional redistribution layer coupling the first active circuitry of the logic chiplet to the second active circuitry of the memory chiplet and the through-package vias; and
the active frontside of the memory chiplet faces the second direction and the top redistribution layer;
the logic chiplet further comprises a backside facing the second direction and the top redistribution layer; and
the logic chiplet is positioned between the additional redistribution layer and the top redistribution layer.

19. The multi-chiplet assembly of claim 18 further comprising an additional logic chiplet directly coupled to the logic chiplet, wherein the additional logic chiplet is positioned between the logic chiplet and the top redistribution layer.

20. A method of manufacturing a multi-chiplet assembly, the method comprising:
electrically coupling a plurality of vias of a main-memory chiplet to a redistribution layer, the main-memory chiplet comprising:
the plurality of vias; and
an active frontside having first active circuitry, wherein the active frontside of the main-memory chiplet faces away from the redistribution layer;
electrically coupling a logic chiplet to the main-memory chiplet, the logic chiplet comprising an active frontside having second active circuitry, wherein:
the active frontside of the main-memory chiplet faces a first direction;
the active frontside of the logic chiplet faces a second direction opposite the first direction; and
the second active circuitry of the logic chiplet is electrically coupled to the redistribution layer by the plurality of vias of the main-memory chiplet.
